(19) United States
(12) Patent Application Publication
(10) Pub. No.: US 2020/0381597 A1
(43) Pub. Date: Dec. 3, 2020

(54) WAVELENGTH CONVERSION MEMBER AND LIGHT-EMITTING DEVICE USING SAME

(71) Applicant: NIPPON ELECTRIC GLASS CO., LTD., Otsu-shi, Shiga (JP)

(72) Inventor: Tadahito FURUYAMA, Otsu-shi (JP)

(21) Appl. No.: 16/970,646

(22) PCT Filed: Mar. 4, 2019
(86) PCT No.: PCT/JP2019/008470

§ 371 Date: Aug. 18, 2020

(30) Foreign Application Priority Data
Mar. 13, 2018 (JP) 2018-045056
Nov. 30, 2018 (JP) 2018-224494

(51) Int. Cl. H01L 33/50

(52) U.S. Cl. CPC H01L 33/504

(57) ABSTRACT

Provided are: a wavelength conversion member capable of reducing the decrease in luminescence intensity with time and the melting of component materials when irradiated with high-power excitation light; a method for producing the same; and a light-emitting device using the wavelength conversion member. A wavelength conversion member 10 comprising: phosphor particles 2 and thermally conductive particles 3 both dispersed into an inorganic binder 1; wherein a refractive index difference between the inorganic binder 1 and the thermally conductive particles 3 being 0.2 or less, and a volume ratio of a content of the inorganic binder 1 to a content of the thermally conductive particles 3 being 80:20 to over 40:below 60.

### TECHNICAL FIELD

The present invention relates to wavelength conversion members for converting the wavelength of light emitted from light emitting diodes (LEDs), laser diodes (LDs) or the like to another wavelength and light-emitting devices using the same.

### BACKGROUND ART

Recently, attention has been increasingly focused on light-emitting devices using LEDs, LDs or like excitation light sources as next-generation light-emitting devices to replace fluorescence lamps and incandescent lamps, from the viewpoint of their low power consumption, small size, light weight, and easy adjustment to light intensity. For example, Patent Literature 1 discloses, as an example of such a next-generation light-emitting device, a light-emitting device in which a wavelength conversion member is disposed on an LED capable of emitting a blue light and absorbs part of the light from the LED to convert it to a yellow light. This light-emitting device emits a white light which is a synthetic light of the blue light emitted from the LED and the yellow light emitted from the wavelength conversion member.

As a wavelength conversion member, there is conventionally used a wavelength conversion member in which phosphor particles are dispersed in a resin matrix. However, when such a wavelength conversion member is used, there arises a problem that the resin is degraded by light from the excitation light source to make it likely that the luminance of the light-emitting device will be low. Particularly, the wavelength conversion member has a problem that the molded resin is degraded by heat and high-energy short-wavelength (blue to ultraviolet) light emitted from the excitation light source to cause discoloration or deformation.

To cope with the above, a wavelength conversion member is proposed which is formed of a fully inorganic solid in which phosphor particles are dispersed and set in, instead of the resin matrix, a glass matrix (see, for example, Patent Literatures 2 and 3). This wavelength conversion member has the feature that glass as the matrix is less likely to be degraded by heat and irradiation light from the LED and therefore less likely to cause problems of discoloration and deformation.

### CITATION LIST

### Patent Literature

### [PTL 1]

### JP-A-2000-208815

### [PTL 2]

### JP-A-2003-258308

### [PTL 3]

### JP-B2-4895541

### SUMMARY OF INVENTION

### Technical Problem

Recently, the power of an LED or an LD for use as an excitation light source is increasing for the purpose of providing higher power. Along with this, the temperature of the wavelength conversion member rises due to heat from the excitation light source and heat emitted from the phosphor irradiated with excitation light, resulting in the problem that the luminescence intensity decreases with time (temperature quenching). Furthermore, in some cases, the temperature rise of the wavelength conversion member becomes significant, so that its component materials (such as the glass matrix) may melt.

In view of the foregoing, the present invention has an object of providing: a wavelength conversion member capable of reducing the decrease in luminescence intensity with time and the melting of component materials when irradiated with high-power excitation light; a method for producing the same; and a light-emitting device using the wavelength conversion member.

### Solution to Problem

A wavelength conversion member according to the present invention is a wavelength conversion member comprising: phosphor particles and thermally conductive particles both dispersed into an inorganic binder; wherein a refractive index difference between the inorganic binder and the thermally conductive particles being 0.2 or less, and a volume ratio of a content of the inorganic binder to a content of the thermally conductive particles being 80:20 to over 40:below 60. When, as in the above structure, the content of the thermally conductive particles in the wavelength conversion member is large, heat of excitation light itself and heat generated from the phosphor particles when the wavelength conversion member is irradiated with the excitation light transmit through the thermally conductive particles and are efficiently released to the outside. Thus, the temperature rise of the wavelength conversion member can be reduced to reduce the decrease in luminescence intensity with time and the melting of the component materials. Furthermore, since the upper limit of the content of the thermally conductive particles in the wavelength conversion member is defined as described above, a small-porosity wavelength conversion member can be obtained. Thus, the proportion of air, which is less thermally conductive, existing in the inside of the wavelength conversion member becomes low, so that the thermal conductivity of the wavelength conversion member can be increased. In addition, light scattering caused by a refractive index difference between the inorganic binder, the thermally conductive particles or the phosphor particles and the air contained in the pores can be reduced, so that the light permeability of the wavelength conversion member can be increased. As a result, the light extraction efficiency of excitation light or fluorescence emitted from the phosphor particles can be increased. Furthermore, since the refractive index difference between the inorganic binder and the thermally conductive particles is small as described above, light scattering due to reflection at the interface between the inorganic binder and thermally conductive particles can be reduced, which also can increase the light extraction efficiency of excitation light or fluorescence.

The wavelength conversion member according to the present invention preferably has a porosity of 10% or less.

In the wavelength conversion member according to the present invention, a distance between a plurality of adjacent ones of the thermally conductive particles and/or a distance from the thermally conductive particles to the phosphor particles adjacent to the thermally conductive particles is preferably 0.08 mm or less. Particularly, it is preferred that a plurality of the thermally conductive particles be in contact with each other and/or the thermally conductive particles be in contact with the phosphor particles. Thus, the distance of heat conduction through the inorganic binder, which is less thermally conductive, becomes short and, in turn, heat conduction paths are formed between the plurality of thermally conductive particles, so that heat generated in the inside of the wavelength conversion member can be easily conducted to the outside.

In the wavelength conversion member according to the present invention, the thermally conductive particles preferably have an average particle diameter D₅₀ of 20 μm or less. Thus, the thermally conductive particles are easily homogeneously dispersed into the inorganic binder. Furthermore, the phosphor particles can also be homogeneously dispersed into the inorganic binder, so that the orientation of fluorescence emitted from the wavelength conversion member is easily increased.

In the wavelength conversion member according to the present invention, the thermally conductive particles preferably have a higher thermal conductivity than the phosphor particles.

In the wavelength conversion member according to the present invention, the thermally conductive particles that can be used are, for example, those made of an oxide ceramic. Specifically, the thermally conductive particles are preferably at least one selected from the group consisting of aluminum oxide, magnesium oxide, yttrium oxide, zinc oxide, and magnesia spinel.

In the wavelength conversion member according to the present invention, the inorganic binder preferably has a softening point of 1000° C. or lower.

In the wavelength conversion member according to the present invention, the inorganic binder preferably has a refractive index (nd) of 1.6 to 1.85.

In the wavelength conversion member according to the present invention, the inorganic binder is preferably glass. In this case, the glass is preferably substantially free of alkali metal component. Alkali metal components contained in glass are likely to form color centers when exposed to excitation light, and may serve as sources of absorption of excitation light and fluorescence to decrease the luminous efficiency. When, as a solution to this, the glass as the inorganic binder has a composition substantially free of alkali metal component, the above inconvenience is less likely to occur and the luminous efficiency of the wavelength conversion member is likely to increase.

In the wavelength conversion member according to the present invention, a difference in coefficient of thermal expansion between the inorganic binder and the thermally conductive particles is preferably 60×10⁻⁷ or less in a temperature range from 30 to 380° C. Thus, during firing in the production process, pores due to the difference in coefficient of thermal expansion between the inorganic binder and the thermally conductive particles are less likely to be produced.

In the wavelength conversion member according to the present invention, a content of the phosphor particles is preferably 1 to 70% by volume.

The wavelength conversion member according to the present invention preferably has a thickness of 500 μm or less.

The wavelength conversion member according to the present invention preferably has a thermal diffusivity of 5×10⁻⁷ m²/s or more.

In the wavelength conversion member according to the present invention, a light entrance surface and/or a light exit surface is preferably antireflection-treated. By doing so, upon incidence of excitation light and exit of fluorescence, the reflection loss at the surface of the member can be reduced.

A light-emitting device according to the present invention includes the above-described wavelength conversion member and a light source operable to irradiate the wavelength conversion member with excitation light.

In the light-emitting device according to the present invention, the light source is preferably a laser diode. Thus, the luminescence intensity can be increased. When a laser diode is used as the light source, the temperature of the wavelength conversion member is likely to rise, which makes it likely that the effects of the present invention are exerted.

### Advantageous Effects of Invention

The present invention enables provision of: a wavelength conversion member capable of reducing the decrease in luminescence intensity with time and the melting of component materials when irradiated with high-power excitation light; a method for producing the same; and a light-emitting device using the wavelength conversion member.

### BRIEF DESCRIPTION OF DRAWINGS

FIG. 1 is a schematic cross-sectional view showing a wavelength conversion member according to one embodiment of the present invention.

FIG. 2 is a schematic side view showing a light-emitting device in which the wavelength conversion member according to the one embodiment of the present invention is used.

FIG. 3 is a photograph of a partial cross section of a wavelength conversion member in Example No. 4.

### DESCRIPTION OF EMBODIMENTS

Hereinafter, an embodiment of the present invention will be described in detail with reference to the drawings. However, the present invention is not at all limited to the following embodiment.

(Wavelength Conversion Member)

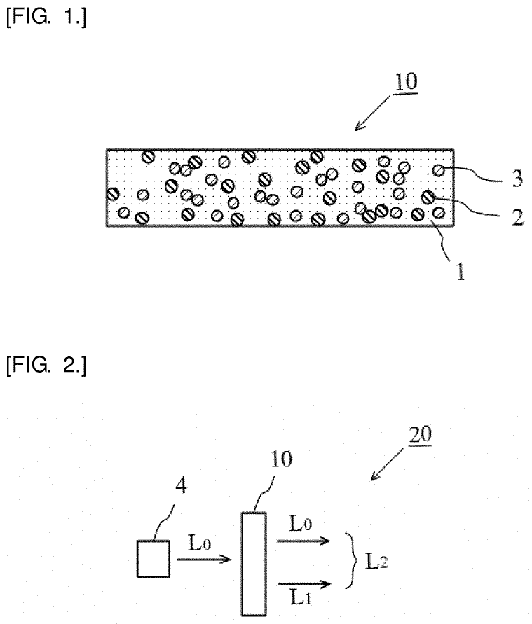

FIG. 1 is a schematic cross-sectional view showing a wavelength conversion member according to an embodiment of the present invention. The wavelength conversion member 10 is formed so that phosphor particles 2 and thermally conductive particles 3 are dispersed into an inorganic binder 1. The wavelength conversion member 10 according to this embodiment is a transmissive wavelength conversion member. When one of the principal surfaces of the wavelength conversion member 10 is irradiated with excitation light, part of the incident excitation light is converted in wavelength to fluorescence by the phosphor particles 2 and the fluorescence is radiated through the other principal surface to the outside. Furthermore, excitation light not converted in wavelength by the phosphor particles 2 is also emitted through the other principal surface to the outside. In other words, synthetic light composed of fluorescence and excitation light is emitted to the outside. There is no particular limitation as to the shape of the wavelength conversion member 10, but the shape is generally a sheet-like shape having a rectangular or circular plan view.

As shown in FIG. 1, in this embodiment, a plurality of thermally conductive particles 3 are adjacent to or in contact with each other. Thus, the lengths of portions of the less thermally conductive inorganic binder 1 existing between the plurality of thermally conductive particles 3 are short. Particularly, heat conduction paths are formed at locations where some thermally conductive particles 3 are in contact with each other. Furthermore, since in this embodiment the thermally conductive particles 3 are adjacent to or in contact with the phosphor particles 2, the lengths of portions of the less thermally conductive inorganic binder 1 existing between the phosphor particles 2 and the thermally conductive particles 3 are short. Particularly, heat conduction paths are formed at locations where the thermally conductive particles 3 are in contact with the phosphor particles 2. The distance between the plurality of adjacent thermally conductive particles 3 and/or the distance from the thermally conductive particles 3 to the phosphor particles 2 adjacent to the thermally conductive particles 3 is preferably 0.08 mm or less and particularly preferably 0.05 mm or less. Thus, heat generated in the phosphor particles 2 is likely to be conducted to the outside, so that an undue increase in temperature of the wavelength conversion member 10 can be prevented.

The distance between the plurality of adjacent thermally conductive particles 3 and the distance from the thermally conductive particles 3 to the phosphor particles 2 adjacent to the thermally conductive particles 3 can be measured from a backscattered electron image of a cross section of the wavelength conversion member 10.

Hereinafter, a detailed description will be given of the components.

The preferred inorganic binder 1 for use is one having a softening point of 1000° C. or lower in consideration of thermal degradation of the phosphor particles 2 in the firing step during production. An example of the inorganic binder 1 just described is glass. Glass has good thermal resistance as compared to organic matrices, such as resin, is easily softened and fluidized by thermal treatment, and therefore has a feature of capability to easily densify the structure of the wavelength conversion member 10. The softening point of the glass is preferably 250 to 1000° C., more preferably 300 to 950° C., still more preferably 400 to 900° C., and particularly preferably 400 to 850° C. If the softening point of the glass is too low, the mechanical strength and chemical durability of the wavelength conversion member 10 may decrease. Furthermore, since the thermal resistance of the glass itself is low, the glass may be softened and deformed by heat generated from the phosphor particles 2. On the other hand, if the softening point of the glass is too high, the phosphor particles 2 may degrade in the firing step during production, so that the luminescence intensity of the wavelength conversion member 10 may decrease. From the perspective of increasing the chemical stability and mechanical strength of the wavelength conversion member 10, the softening point of the glass is preferably not lower than 500° C., more preferably not lower than 600° C., still more preferably not lower than 700° C., yet still more preferably not lower than 800° C. and particularly preferably not lower than 850° C. Examples of the glass just described include borosilicate-based glasses, silicate-based glasses, and aluminosilicate-based glasses. However, as the softening point of the glass increases, the firing temperature increases, resulting in a tendency to raise the production cost. If, additionally, the thermal resistance of the phosphor particles 2 is low, the phosphor particles 2 may degrade during firing. Therefore, in the case of producing the wavelength conversion member 10 at low cost or in the case of using phosphor particles 2 having low thermal resistance, the softening point of the glass is preferably not higher than 550° C., more preferably not higher than 530° C., still more preferably not higher than 500° C., yet still more preferably not higher than 480° C., and particularly preferably not higher than 460° C. Examples of the glass just described include tin-phosphate-based glasses, bismuthate-based glasses, and tellurite-based glasses.

The glass forming the inorganic binder 1 is preferably substantially free of alkali metal component. The reason for this is that alkali metal components contained in glass are likely to form color centers when exposed to excitation light, and may serve as sources of absorption of excitation light and fluorescence to decrease the luminous efficiency.

The glass for use as the inorganic binder 1 is generally a glass powder. The average particle diameter of the glass powder is preferably 50 μm or less, more preferably 30 μm or less, still more preferably 10 μm or less, and particularly preferably 5 μm or less. If the average particle diameter of the glass powder is too large, a dense sintered body is less likely to be obtained. There is no particular limitation as to the lower limit of the average particle diameter of the glass powder, but it is generally 0.5 μm or more and preferably 1 μm or more.

The average particle diameter used herein refers to a value measured by laser diffractometry and indicates the particle diameter (D₅₀) when in a volume-based cumulative particle size distribution curve as determined by laser diffractometry the integrated value of cumulative volume from the smaller particle diameter is 50%.

The refractive index of the inorganic binder 1 is preferably selected to be near the refractive index of the thermally conductive particles 3. For example, the refractive index (nd) of the inorganic binder 1 is preferably 1.6 to 1.85 and more preferably 1.65 to 1.8.

There is no particular limitation as to the type of the phosphor particles 2 so long as they emit fluorescence upon incidence of excitation light. Specific examples of the phosphor particles 2 include at least one selected from the group consisting of, for example, oxide phosphor, nitride phosphor, oxynitride phosphor, chloride phosphor, oxychloride phosphor, sulfide phosphor, oxysulfide phosphor, halide phosphor, chalcogenide phosphor, aluminate phosphor, halophosphoric acid chloride phosphor, and garnet-based compound phosphor. With the use of a blue light as the excitation light, a phosphor capable of emitting as the fluorescence, for example, a green light, a yellow light or a red light can be used.

The average particle diameter of the phosphor particles 2 is preferably 1 to 50 μm and particularly preferably 5 to 30 μm. If the average particle diameter of the phosphor particles 2 is too small, the luminescence intensity is likely to decrease. On the other hand, if the average particle diameter of the phosphor particles 2 is too large, the luminescent color tends to be uneven. Therefore, from the perspective of increasing the evenness of the luminescent color, the average particle diameter of the phosphor particles 2 is preferably not more than 20 μm, more preferably not more than 10 μm, and particularly preferably less than 10 μm.

The content of the phosphor particles 2 in the wavelength conversion member 10 is preferably 1 to 70% by volume, more preferably 1 to 50% by volume, and particularly preferably 1 to 30% by volume. If the content of the phosphor particles 2 is too small, a desired luminescence intensity is less likely to be obtained. On the other hand, if the content of the phosphor particles 2 is too large, the thermal diffusivity of the wavelength conversion member 10 decreases, so that the heat dissipation properties are likely to decrease.

The thermally conductive particles 3 have a higher thermal conductivity than the inorganic binder 1. Particularly, the thermally conductive particles 3 preferably have a higher thermal conductivity than the inorganic binder 1 and the phosphor particles 2. Specifically, the thermal conductivity of the thermally conductive particles 3 is preferably 5 W/m·K or more, more preferably 20 W/m·K or more, still more preferably 40 W/m·K or more, and particularly preferably 50 W/m·K or more.

The preferred thermally conductive particles 3 are an oxide ceramic. Specific examples of the oxide ceramic include aluminum oxide, magnesium oxide, yttrium oxide, zinc oxide, and magnesia spinel (MgAl₂O₄). These oxide ceramics may be used singly or in a mixture of two or more of them. Of these, aluminum oxide or magnesium oxide, which has a relatively high thermal conductivity, is preferably used and, particularly, magnesium oxide, which has a high thermal conductivity and less light absorption, is more preferably used. Magnesia spinel is preferred in terms of relatively high availability and relative inexpensiveness.

The average particle diameter (D₅₀) of the thermally conductive particles 3 is preferably 20 μm or less, more preferably 15 μm or less, and particularly preferably 10 μm or less. If the average particle diameter of the thermally conductive particles 3 is too large, the thermally conductive particles 3 are less likely to be homogeneously dispersed into the inorganic binder. In addition, the distance between the phosphor particles 2 becomes too large, so that phosphor emitted from the wavelength conversion member 10 is likely to cause unevenness in orientation. If the average particle diameter of the thermally conductive particles 3 is too small, the specific surface area of the thermally conductive particles 3 becomes large and the density of the wavelength conversion member 10 is likely to decrease. Therefore, the average particle diameter of the thermally conductive particles 3 is preferably not less than 0.1 μm, more preferably not less than 1 μm, still more preferably not less than 3 μm, and even still more preferably not less than 5 μm.

The volume ratio of the content of the inorganic binder 1 to the content of the thermally conductive particles 3 in the wavelength conversion member 10 is 80:20 to over 40:below 60, preferably 80:20 to 41:59, more preferably 75:25 to 50:50, still more preferably 73:27 to 55:45, and particularly preferably 72:28 to 60:40. If the content of the thermally conductive particles 3 is too small (i.e., the content of the inorganic binder 1 is too large), a desired heat dissipation effect is less likely to be achieved. On the other hand, if the content of the thermally conductive particles 3 is too large (i.e., the content of the inorganic binder 1 is too small), the amount of pores in the wavelength conversion member 10 increases. Therefore, a desired heat dissipation effect cannot be achieved, and light scattering in the inside of the wavelength conversion member 10 becomes excessive, so that the fluorescence intensity is likely to decrease. These inconveniences when the content of the thermally conductive particles 3 is too large tend to appear prominently particularly when the particle diameter of the thermally conductive particles 3 is small.

The total amount of the inorganic binder 1 and the thermally conductive particles 3 in the wavelength conversion member 10 is adjusted, in consideration of the content of the phosphor particles 2, preferably in a range of 30 to 99% by volume, more preferably in a range of 50 to 99% by volume, and particularly preferably in a range of 70 to 99% by volume.

The porosity (% by volume) in the wavelength conversion member 10 is preferably 10% or less, more preferably 5% or less, and particularly preferably 3% or less. If the porosity is too high, the heat dissipation effect is likely to decrease. In addition, light scattering in the inside of the wavelength conversion member 10 becomes excessive, so that the fluorescence intensity is likely to decrease.

The refractive index difference (nd) between the inorganic binder 1 and the thermally conductive particles 3 is 0.2 or less, preferably 0.15 or less, and particularly preferably 0.1 or less. If the refractive index difference is too large, reflection at the interface between the inorganic binder 1 and the thermally conductive particles 3 increases, so that light scattering becomes excessive and, thus, the fluorescence intensity is likely to decrease.

The refractive index difference between the inorganic binder 1 and the thermally conductive particles 3 can be calculated from the values of the refractive indices of these materials. Alternatively, the wavelength conversion member 10 after the sintering can be measured in terms of refractive index difference between the inorganic binder 1 and the thermally conductive particles 3, using a commercially available transmissive phase-shift laser interference microscope.

The difference in coefficient of thermal expansion (at 30 to 380° C.) between the inorganic binder 1 and the thermally conductive particles 3 is preferably 60×10⁻⁷ or less and particularly preferably 50×10⁻⁷ or less. Thus, during firing in the production process, pores due to the difference in coefficient of thermal expansion between the inorganic binder and the thermally conductive particles are less likely to be produced.

The thickness of the wavelength conversion member 10 is preferably 500 μm or less and more preferably 300 μm or less. If the thickness of the wavelength conversion member 10 is too large, scattering and absorption of light in the wavelength conversion member 10 become too much, so that the efficiency of emission of fluorescence tends to decrease. In addition, the thermal conductivity decreases and, therefore, the temperature of the wavelength conversion member 10 becomes high, so that a decrease in luminescence intensity with time and melting of the component materials are likely to occur. The lower limit of the thickness of the wavelength conversion member 10 is preferably about 100 μm. If the thickness of the wavelength conversion member 10 is too small, its mechanical strength is likely to decrease. In addition, because the content of the phosphor particles 2 needs to be increased in order to obtain a desired luminescent color, the content of the thermally conductive particles 3 becomes relatively small, so that the thermal conductivity is likely to decrease.

The light entrance surface and/or the light exit surface of the wavelength conversion member 10 is preferably antireflection-treated. By doing so, upon incidence of excitation light and exit of fluorescence, the reflection loss at the surface of the member can be reduced. Examples of the antireflection treatment include an antireflection film, such as a dielectric multi-layer, and a microstructure, such as a moth eye structure. Furthermore, when a bandpass filter is provided on the light entrance surface of the wavelength conversion member 10, the leakage of fluorescence produced in the inside of the wavelength conversion member 10 to the light entrance surface side can be reduced.

When the wavelength conversion member 10 has the above structure, it has excellent thermal diffusion properties. Specifically, the thermal diffusivity of the wavelength conversion member 10 is preferably 5×10⁻⁷ m²/s or more, more preferably 6×10⁻⁷ m²/s or more, still more preferably 7×10⁻⁷ m²/s or more, and particularly preferably 8×10⁻⁷ m²/s or more.

The wavelength conversion member 10 may be used by joining it to a different heat dissipating member made of metal, ceramic or so on. By doing so, heat generated in the wavelength conversion member 10 can be more efficiently released from the outside.

(Method for Producing Wavelength Conversion Member)

An example of a method for producing the wavelength conversion member 10 is a method (i) of pressing a powder mixture containing the inorganic binder 1, the phosphor particles 2, and the thermally conductive particles 3 in a mold to obtain a preform and firing the preform. In this case, the preform is preferably fired in an atmosphere of a reduced pressure, such as vacuum. By doing so, a low-porosity wavelength conversion member can be easily obtained.

Alternatively, another example of a method for producing the wavelength conversion member 10 is a method (ii) of adding organic components, including a resin, a solvent, and a plasticizer, to a powder mixture containing the inorganic binder 1, the phosphor particles 2, and the thermally conductive particles 3 and kneading them to form a slurry, forming the slurry into a shape on a resin film made of, for example, polyethylene terephthalate, by the doctor blade method or other methods, heating and drying the slurry to obtain a green sheet preform, and firing the green sheet preform. The firing of the green sheet preform is preferably performed by heating the preform at the decomposition temperature of the resin or higher in an air atmosphere and then heating the preform to a firing temperature in an atmosphere of a reduced pressure. By doing so, a low-porosity wavelength conversion member can be easily obtained.

In the above production methods (i) and (ii), the firing temperature is preferably 1000° C. or lower, more preferably 950° C. or lower, and particularly preferably 900° C. or lower. If the firing temperature is too high, the phosphor particles 2 are likely to thermally degrade. If the firing temperature is too low, a dense sintered body is less likely to be obtained. Therefore, the firing temperature is preferably not lower than 250° C., more preferably not lower than 300° C., and particularly preferably not lower than 400° C.

The production methods (i) and (ii) are effective when the volume ratio of the thermally conductive particles 3 to the total amount of the inorganic binder 1 and the thermally conductive particles 3 is approximately 40% or less. If the volume ratio of the thermally conductive particles 3 is too high, a dense sintered body is less likely to be obtained.

Still another example of a method for producing the wavelength conversion member 10 is a method (iii) of hot-pressing a powder mixture containing the inorganic binder 1, the phosphor particles 2, and the thermally conductive particles 3. The hot pressing can be performed by a hot press, a spark plasma sintering machine or a hot isostatic press. With the use of these machines, a dense sintered body can be easily obtained. The hot pressing is preferably performed in an atmosphere of a reduced pressure. Thus, debubbling during the firing can be promoted, so that a dense sintered body is easily obtained.

The temperature during the hot pressing is preferably 1000° C. or lower, more preferably 950° C. or lower, and particularly preferably 900° C. or lower. If the temperature during the hot pressing is too high, the phosphor particles 2 are likely to thermally degrade. On the other hand, if the temperature during the hot pressing is too low, a dense sintered body is less likely to be obtained. Therefore, the temperature is preferably not lower than 250° C., more preferably not lower than 300° C., and particularly preferably not lower than 400° C.

The pressure during the hot pressing is appropriately adjusted, in order to provide a dense sintered body, for example, preferably in a range of 10 to 100 MPa and particularly preferably in a range of 20 to 60 MPa.

There is no particular limitation as to the material for the sintering mold and, for example, a carbon-made mold or a ceramic-made mold can be used.

The above production method (iii) easily provides a dense sintered body and is therefore effective particularly when the volume ratio of the thermally conductive particles 3 to the total amount of the inorganic binder 1 and the thermally conductive particles 3 is large (for example, 35% or more or over 40%).

(Light-Emitting Device)

FIG. 2 is a schematic side view showing a light-emitting device in which the wavelength conversion member according to the above-described embodiment is used. As shown in FIG. 2, the light-emitting device 20 includes the wavelength conversion member 10 and a light source 4. Excitation light L₀ emitted from the light source 4 is converted to fluorescence L₁ by the wavelength conversion member 10. Furthermore, part of the excitation light L₀ passes through the wavelength conversion member 10 as it is. Therefore, the wavelength conversion member 10 emits synthetic light L₂ composed of the excitation light L₀ and the fluorescence L₁. For example, when the excitation light L₀ is a blue light and the fluorescence L₁ is a yellow light, a white synthetic light L₂ can be provided.

Since the above-described wavelength conversion member 10 is used in the light-emitting device 20, heat generated by irradiating the wavelength conversion member 10 with excitation light can be efficiently released to the outside. Thus, an undue rise in temperature of the wavelength conversion member 10 can be prevented.

Examples of the light source 4 include an LED and an LD. From the perspective of increasing the luminescence intensity of the light-emitting device 20, an LD, which is capable of emitting high-intensity light, is preferably used as the light source 4. When an LD is used as the light source, the temperature of the wavelength conversion member 10 is likely to rise, which makes it likely that the effects of the present invention are exerted.

### EXAMPLES

Hereinafter, the wavelength conversion member according to the present invention will be described in detail with reference to examples, but the present invention is not limited to the following examples.

Table 1 shows working examples (Nos. 1 to 10) of the present invention and comparative examples (Nos. 11 to 12).

TABLE 1

| | | No. | No. | No. | No. | No. | No. | No. | No. | No. | No. | No. | No. |
|---|---|---|---|---|---|---|---|---|---|---|---|---|---|
| | | 1 | 2 | 3 | 4 | 5 | 6 | 7 | 8 | 9 | 10 | 11 | 12 |
| Thermally | Type | MgO | MgO | MgO | MgO | Al₂O₃ | Al₂O₃ | MgO | MgO | MgAl₂O₄ | MgO | MgO | MgO |
| Conductive | Refractive | 1.73 | 1.73 | 1.73 | 1.73 | 1.76 | 1.76 | 1.73 | 1.73 | 1.72 | 1.73 | 1.73 | 1.73 |
| Particles | index nd1 | | | | | | | | | | | | |
| | CTE α1 | 130 | 130 | 130 | 130 | 72 | 72 | 130 | 130 | 74 | 130 | 130 | 130 |
| | (×10⁻⁷/° C.) | | | | | | | | | | | | |
| | Average | 8 | 8 | 8 | 8 | 9 | 9 | 8 | 8 | 21 | 43 | 8 | 8 |
| | particle | | | | | | | | | | | | |
| | diameter (μm) | | | | | | | | | | | | |
| Inorganic | Type | A | A | A | A | A | C | C | D | A | A | A | B |
| Binder | Softening point | 790 | 790 | 790 | 790 | 790 | 380 | 380 | 450 | 790 | 790 | 790 | 850 |
| | CTE α2 | 79 | 79 | 79 | 79 | 79 | 121 | 121 | 98 | 79 | 79 | 79 | 51 |
| | (×10⁻⁷/° C.) | | | | | | | | | | | | |
| | Difference | 51 | 51 | 51 | 51 | 7 | 49 | 9 | 32 | 5 | 51 | 51 | 79 |
| | in CTE | | | | | | | | | | | | |
| | \|α1 − α2\| | | | | | | | | | | | | |
| | Refractive | 1.71 | 1.71 | 1.71 | 1.71 | 1.71 | 1.82 | 1.82 | 1.91 | 1.71 | 1.71 | 1.71 | 1.49 |
| | index nd2 | | | | | | | | | | | | |
| | Refractive index | 0.02 | 0.02 | 0.02 | 0.02 | 0.05 | 0.09 | 0.09 | 0.18 | 0.01 | 0.02 | 0.02 | 0.24 |
| | difference | | | | | | | | | | | | |
| | \|nd1 − nd2\| | | | | | | | | | | | | |
| Inorganic Binder:Thermally | | 70:30 | 60:40 | 50:50 | 50:50 | 50:50 | 50:50 | 70:30 | 70:30 | 60:40 | 70:30 | 90:10 | 70:30 |
| Conductive Filler | | | | | | | | | | | | | |
| (volume ratio) | | | | | | | | | | | | | |
| Phosphor | Type | YAG | YAG | YAG | YAG | YAG | YAG | CASN | CASN | YAG | YAG | YAG | YAG |
| Powder | Average particle | 22 | 22 | 22 | 22 | 22 | 22 | 15 | 15 | 22 | 22 | 22 | 22 |
| | diameter (μm) | | | | | | | | | | | | |
| | Content | 3 | 3 | 3 | 3 | 3 | 3 | 3 | 3 | 3 | 3 | 3 | 3 |
| | (% by volume) | | | | | | | | | | | | |

| | | | | | | | | | | | | |
|---|---|---|---|---|---|---|---|---|---|---|---|---|
| Thermal treatment | 820 | 820 | 820 | 820 | 820 | 450 | 450 | 500 | 820 | 820 | 820 | 800 |
| temperature (° C.) | | | | | | | | | | | | |
| Thermal treatment method | V | V | V | HP | HP | HP | V | V | V | V | V | V |
| (V: firing under reduced | | | | | | | | | | | | |
| pressure, HP: hot pressing) | | | | | | | | | | | | |
| Porosity (%) | 0.0 | 5.6 | 8.7 | 0.2 | 8.0 | 7.6 | 4.5 | 4.2 | 0.0 | 0.0 | 0.0 | 4.5 |
| Thermal diffusivity | 7.3 | 8.4 | 9.0 | 14.1 | 6.5 | 7.1 | 6.3 | 5.9 | 7.2 | 9.0 | 3.5 | 6.7 |
| (×10⁻⁷ m²/s) | | | | | | | | | | | | |
| Heat dissipation | 62 | 58 | 50 | 45 | 80 | 89 | 69 | 70 | 82 | 55 | Poor | 58 |
| (Sample temp. (° C.) | | | | | | | | | | | | |
| upon laser irradiation) | | | | | | | | | | | | |
| Light permeability | Good | Good | Good | Good | Good | Good | Good | Good | Good | Good | Good | Poor |
| Luminescence unevenness | Good | Good | Good | Good | Good | Good | Good | Good | Fair | Poor | Good | Good |

Thermally conductive particles, an inorganic binder, and phosphor particles were mixed to give each ratio described in Table 1, thus obtaining a powder mixture. In the table, the content of the phosphor particles is a content in the powder mixture and the remainder is accounted for by the thermally conductive particles and the inorganic binder. The materials used were as follows.

(a) Thermally Conductive Particles

MgO (thermal conductivity: approx. 42 W/m·K, average particle diameter D₅₀: 8 μm, refractive index (nd): 1.73)

Al₂O₃ (thermal conductivity: approx. 20 W/m·K, average particle diameter D₅₀: 9 μm, refractive index (nd): 1.76)

MgAl₂O₄ (thermal conductivity: approx. 16 W/m·K, average particle diameter D₅₀: 21 μm)

(b) Inorganic Binder

Inorganic binder A (barium silicate-based glass powder, softening point: 790° C., refractive index (nd): 1.71, average particle diameter D₅₀: 2.5 μm)

Inorganic binder B (borosilicate-based glass powder, softening point: 775° C., refractive index (nd): 1.49, average particle diameter D₅₀: 1.3 μm)

Inorganic binder C (tin-phosphate-based glass powder, softening point: 380° C., refractive index (nd): 1.82, average particle diameter D₅₀: 3.8 μm)

Inorganic binder D (bismuth-based glass powder, softening point: 450° C., refractive index (nd): 1.91, average particle diameter D₅₀: 2.7 μm)

(c) Phosphor Particles

YAG phosphor particles (Y₃Al₅O₁₂, average particle diameter: 22 μm)

CASN phosphor particles (CaAlSiN₃, average particle diameter: 15 μm)

Each of the wavelength conversion members of Nos. 1 to 3 and 7 to 12 in Table 1 was produced in the following manner. The above-described obtained powder mixture was put into a 30 mm×40 mm mold and pressed at a pressure of 25 MPa in the mold, thus producing a preform. The obtained preform was raised in temperature to the thermal treatment temperature shown in Table 1 under a vacuum atmosphere, held for 20 minutes (fired under a reduced pressure), and then slowly cooled to ordinary temperature with introduction of N₂ gas to return the atmosphere to the atmospheric pressure. The obtained sintered body was cut and polished to obtain a rectangular plate-shaped wavelength conversion member with 5 mm×5 mm×0.5 mm.

Each of the wavelength conversion members of Nos. 4 to in Table 1 was produced in the following manner. The above-described obtained powder mixture was put into a 30 mm×40 mm mold and pressed at a pressure of 25 MPa in the mold, thus producing a preform. The obtained preform was loaded into a 30 mm×40 mm carbon-made mold placed in a hotpress furnace (Hi-multi 5000) manufactured by Fuji Dempa Kogyo Co., Ltd. and subjected to hot pressing. As the conditions of the hot pressing, the powder mixture was raised in temperature to the thermal treatment temperature shown in Table 1 under a vacuum atmosphere, pressed at a pressure of 40 MPa for 20 minutes, and then slowly cooled to ordinary temperature with introduction of N₂ gas. The obtained sintered body was cut and polished to obtain a rectangular plate-shaped wavelength conversion member with 5 mm×5 mm×0.5 mm.

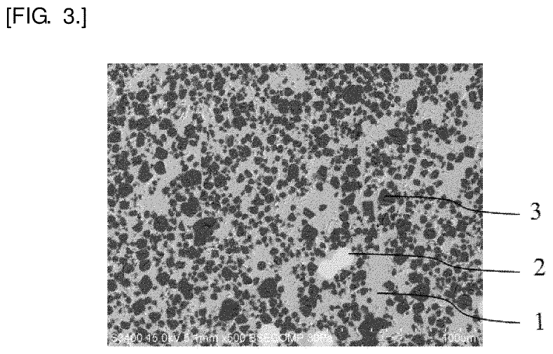

The obtained wavelength conversion members were evaluated in terms of porosity, thermal diffusivity, heat dissipation property, light permeability, and luminescence unevenness in the following manners. The results are shown in Table 1. Furthermore, a photograph of a partial cross section of the wavelength conversion member of No. 4 is shown in FIG. 3.

The porosity was obtained by binarizing a photograph of a backscattered electron image of a cross section of each wavelength conversion member using an image analysis software Winroof and calculating the porosity from the proportion of area of pores occupying in the obtained processed image.

The thermal diffusivity was measured with a thermal diffusivity measurement system ai-phase manufactured by ai-Phase Co., Ltd.

The heat dissipation property was measured in the following manner. Two 30 mm×30 mm×2 mm aluminum sheets with a 3 mm-diameter opening formed in the center were prepared. The wavelength conversion member was sandwiched and secured between the two aluminum sheets. The wavelength conversion member was secured to be located substantially in the center of the aluminum sheets and exposed from the openings of both the aluminum sheets. The exposed wavelength conversion member was irradiated, through the opening of one of the aluminum sheets, with excitation light (with a wavelength of 445 nm and a power of 1.8 W) from an LD for 10 minutes, and the temperature of the surface of the wavelength conversion member opposite to the laser-irradiated surface thereof was measured with a thermography camera manufactured by FLIR Systems, Inc. As for the wavelength conversion member where the glass matrix melted, it was evaluated to be “Poor”.

The light permeability was determined, with the obtained wavelength conversion member placed on a paper with characters under a 1000-lux fluorescent lamp, by whether or not the shadows of the characters could be visually recognized. The wavelength conversion members where the character shadows could be visually recognized were determined to be “Good”, whereas the wavelength conversion member where the character shadows could not be visually recognized was determined to be “Poor”.

The luminescence unevenness was evaluated in the following manner. In the above heat dissipation property test, a white reflector was placed 1 m distant from the light exit side of the wavelength conversion member and whether or not light projected onto the white reflector had color unevenness was confirmed. The wavelength conversion members for which color unevenness was not confirmed were evaluated to be “Good”, the wavelength conversion member for which color unevenness was slightly confirmed was evaluated to be “Fair”, and the wavelength conversion member for which color unevenness was confirmed was evaluated to be “Poor”.

As is obvious from Table 1, the wavelength conversion members of Nos. 1 to 10, which were working examples, exhibited high thermal diffusivities of 5.9×10⁻⁷ m²/s or more and, in the heat dissipation property test, exhibited relatively low temperatures of 45 to 89° C. Furthermore, the wavelength conversion members of Nos. 1 to 8 where thermally conductive particles having small average particle diameters of 8 to 9 μm were used exhibited less color unevenness and therefore excellent homogeneity of emitted light. In contrast, the wavelength conversion member of No. 11, which was a comparative example, had an excessively small content of thermally conductive particles and therefore exhibited a low thermal diffusivity of 3.5×10⁻⁷ m²/s, and its glass matrix melted in the heat dissipation property test. The wavelength conversion member of No. 12 had a large refractive index difference of 0.24 between the thermally conductive particles and the inorganic binder, therefore caused excessively large light scattering at the interface between them, and exhibited “Poor” light permeability.

### INDUSTRIAL APPLICABILITY

The wavelength conversion member according to the present invention is suitable as a component of a general lighting, such as a white LED, or a special lighting (for example, a light source for a projector, a light source for a vehicle headlight or a light source for an endoscope).

### REFERENCE SIGNS LIST

1 inorganic binder
2 phosphor particles
3 thermally conductive particles
4 light source
10 wavelength conversion member
20 light-emitting device

1: A wavelength conversion member comprising:
phosphor particles and thermally conductive particles both dispersed into an inorganic binder;
wherein a refractive index difference between the inorganic binder and the thermally conductive particles being 0.2 or less, and
a volume ratio of a content of the inorganic binder to a content of the thermally conductive particles being 80:20 to over 40:below 60.

2: The wavelength conversion member according to claim 1, having a porosity of 10% or less.

3: The wavelength conversion member according to claim 1, wherein a distance between a plurality of adjacent ones of the thermally conductive particles and/or a distance from the thermally conductive particles to the phosphor particles adjacent to the thermally conductive particles is 0.08 mm or less.

4: The wavelength conversion member according to claim 1, wherein a plurality of the thermally conductive particles are in contact with each other and/or the thermally conductive particles are in contact with the phosphor particles.

5: The wavelength conversion member according to claim 1, wherein the thermally conductive particles have an average particle diameter D₅₀ of 20 μm or less.

6: The wavelength conversion member according to claim 1, wherein the thermally conductive particles have a higher thermal conductivity than the phosphor particles.

7: The wavelength conversion member according to claim 1, wherein the thermally conductive particles are made of an oxide ceramic.

8: The wavelength conversion member according to claim 7, wherein the thermally conductive particles are at least one selected from the group consisting of aluminum oxide, magnesium oxide, yttrium oxide, zinc oxide, and magnesia spinel.

9: The wavelength conversion member according to claim 1, wherein the inorganic binder has a softening point of 1000° C. or lower.

10: The wavelength conversion member according to claim 1, wherein the inorganic binder has a refractive index (nd) of 1.6 to 1.85.

11: The wavelength conversion member according to claim 1, wherein the inorganic binder is glass.

12: The wavelength conversion member according to claim 11, wherein the glass is substantially free of alkali metal component.

13: The wavelength conversion member according to claim 1, wherein a difference in coefficient of thermal expansion between the inorganic binder and the thermally conductive particles is 60×10⁻⁷ or less in a temperature range of 30 to 380° C.

14: The wavelength conversion member according to claim 1, wherein a content of the phosphor particles is 1 to 70% by volume.

15: The wavelength conversion member according to claim 1, having a thickness of 500 μm or less.

16: The wavelength conversion member according to claim 1, having a thermal diffusivity of 5×10⁻⁷ m²/s or more.

17: The wavelength conversion member according to claim 1, wherein a light entrance surface and/or a light exit surface is anti reflection-treated.

18: A light-emitting device comprising: the wavelength conversion member according to claim 1; and a light source operable to irradiate the wavelength conversion member with excitation light.

19: The light-emitting device according to claim 18, wherein the light source is a laser diode.
